(19) United States
(12) Patent Application Publication
(10) Pub. No.: US 2008/0089039 A1
(43) Pub. Date: Apr. 17, 2008

(54) Method for Micropacking of Electrical or Electrochemical Devices and Micropackage

(75) Inventor: John Gregory, Alpharetta, GA (US)

Correspondence Address: FLEIT KAIN GIBBONS GUTMAN BONGINI & BIANCO, 21355 EAST DIXIE HIGHWAY, SUITE 115, MIAMI, FL, 33180, US

(73) Assignee: Intraglobal Corporation, Alpharetta, GA (US)

(21) Appl. No.: 11/576,153

(22) PCT Filed: Sep. 28, 2005
(86) PCT No.: PCT/US05/34905

§ 371 Date: Mar. 28, 2007

Related U.S. Application Data
(60) Provisional application No. 60/614,322, filed on Sep. 28, 2004.
(60) Provisional application No. 60/614,760, filed on Sep. 30, 2004.

(51) Int. Cl. H05K 1/00; H05K 3/34

(52) U.S. Cl. 361/749; 29/840

(57) ABSTRACT

A micropackage, an interposer, in which a flexible dielectric plastic substrate composed of a dielectric layer with a layer of conductive film (copper) on one surface is photo-imaged to define at least two electrical interconnects each including a tab formed in the copper film. The interconnects extend out over the edges of the plastic substrate in at least two directions to form at least two flanges. A cavity is formed in the plastic substrate such that the tabs of the at least two interconnects extend into said cavity. An electrical device or an electro mechanical device having contacts is received in the cavity of the plastic substrate with its contacts engaged with and bonded to the tabs of the interconnects. The method of making, and the use of the interposer in a further substrate, e.g. a PCB, that contains electrical connections or circuitry to which the interposer is connected to by the flanges.

### BACKGROUND OF THE INVENTION

1. Field of the Invention

The invention relates to a method for micropackaging electrical or electro-mechanical devices, and a micropackage. More particularly, the invention relates to a method for micropackaging wherein an electrical or electro mechanical device is embedded in a flexible plastic substrate and further relates to a micropackage that has such a device embedded in a flexible plastic substrate.

2. Prior Art

In the past, electrical and electro-mechanical devices have been package by surface mounting the devices using wire bonding or flip chip technology. Since the electrical or electromechanical component is rigid, if surface mounted on a flexible substrate, there is a danger that the component or one or more of the connections to the flexible substrate will pop-off or disconnect when the substrate is flexed.

### SUMMARY OF THE INVENTION

Accordingly, the principal object of the present invention is to provide a method and device that solves the above disadvantage of the prior art. Therefore the present invention provides a method for micropackaging electrical or electromechanical devices on a flexible substrate, and a micropackage including a flexible substrate that will not pop-off or lose connections when the substrate is flexed.

The above is achieved by a novel method for micropackaging that embeds an electrical or electro mechanical device in a flexible plastic substrate, and by a micropackage that has the device embedded in a flexible plastic substrate. The embedding of the device or component in the flexible substrate will enhance the procedure for printing conductive antennae on labels, cartons and other packaging techniques. For example, polyethylene or similar material which will facilitate the printing of conductive ink or a conductive medium which will establish an electrical pathway between similar components placed on a common surface of material. Any of several printing methods may be employed including screen print, rotogravure, offset and foil stamping.

A further object of the invention is to provide a micropackage comprising:
a. a flexible dielectric plastic substrate composed of a dielectric layer with a layer of conductive film on one surface;
b. at least two electrical interconnects each including a tab formed in the copper film on said one surface, said interconnects extending out over the edges of the plastic substrate in at least two directions to form at least two flanges;
c. a cavity formed in said plastic substrate such that the tabs of the at least two interconnects extend into said cavity; and
d. one of an electrical device and an electro mechanical device having contacts received in the cavity of the plastic substrate with its contacts engaged with and bonded to the tabs of the interconnects.

The micropackage according to above can be modified wherein the substrate is profiled to provide orientation when mounting. Also, preferably, the conductive film is copper. The flanges can have a shallow V-shaped recess in their free edges to act as an ink capillary. In the micropackage a slight space is made to exist adjacent the device received in the cavity, and preferably, at least one corner of the cavity has a relief recess. A conformal coating covers the device, top and bottom.

It is a further object of the invention to provide a method of making a micropackage comprising the steps of:
a. providing a flexible dielectric plastic substrate composed of a dielectric layer with a layer of conductive film on one surface;
b. forming at least two electrical interconnects each including a tab in the copper film on said one surface, with said interconnects extending out over the edges of the plastic substrate in at least two directions to form at least two flanges;
c. forming a cavity in said plastic substrate such that the tabs of the at least two interconnects extend into said cavity;
d. positioning one of an electrical device and an electro mechanical device having contacts in the cavity of the plastic substrate with its contacts engaged with the tabs of the interconnects; and
e. bonding the contacts to the tabs.

The method of making a micropackage according to the above can include the further step of profiling the substrate to provide orientation when mounting.

Preferably, in the above method, the conductive film is copper. Also, the flanges can be formed with a shallow V-shaped recess in their free edges to act as an ink capillary. Further the method can be practiced including the step of providing relief for the device received in the cavity. Also, a conformal coating can be coated on the device.

As a still further object of the present invention, a micropackage can be provided comprising the micropackage of as first described above, as an interposer, mounted in a cavity in a second substrate or PCB having electrical connections; and the flanges of the interposer being fixed to the electrical connections. The micropackage according to the above can further include an antenna on the second substrate coupled to the electrical connections. The antenna can be a conductive ink.

The invention has for another of its objects a method of making a micropackage according to the above wherein the micropackage first described is used as an interposer, and the interposer is mounted in a cavity in a second substrate or PCB having electrical connections, and the interposer are fixed to the electrical connections. Further, an antenna can be formed on the second substrate coupled to the electrical connections. The antenna can be formed using conductive ink.

Other and further objects and advantages will become apparent form the following detailed description of embodiments of the invention when taken together with the appended drawings as described below.

### BRIEF DESCRIPTION OF THE DRAWINGS

FIG. 1 shows schematically a top plan view of a micropackage according to the present invention;

FIG. 2 shows schematically a side view of the micropackage shown in FIG. 1;

FIG. 3 shows schematically a bottom view of the micropackage shown in FIG. 1;

FIGS. 4A, B and C show schematically, respectively, a top, bottom and side view of another embodiment of the invention;

FIGS. 5A, B and C show schematically, respectively, a side view of a punch tool, a bottom view of the tool, and the punch pattern;

FIG. 6 shows a micropackage comprising an RFID device embedded in a substrate and interconnected with an antenna;

FIG. 7 is an enlarged view of interconnect between the RFID device shown in FIG. 6 and the antenna;

FIG. 8 shows schematically in side view an RFID device mounted in a flexible substrate, in turn, mounted on a flexible substrate and connected with a printed antenna;

FIG. 9 schematically shows a carton with a label or a substrate fixed to its top; FIG. 10 schematically shows in side view a label;

FIG. 11 schematically shows in side view another label; and

FIG. 12 schematically shows in side view a section through a wall of a carton.

### DETAILED DESCRIPTION OF PREFERRED EMBODIMENTS OF THE INVENTION

Essentially, the method of the present invention consists of providing an interposer formed to connect an electrical device (i.e. semiconductor, resistor, capacitor) or a electro mechanical device (switch, sensor, connector) to a flexible substrate by ultra sonically bonding a circuit interconnect to the device by employing a method of embedding the device as described in WO 01/65595 A2, the contents of which are herein incorporated by reference in their entirety. This method consists essentially of providing a flexible dielectric substrate laminated with a conductive foil, preferably copper, on opposite sides of the substrate. First, an interconnecting conductive circuit is created on the top side of the laminated dielectric substrate by selectively removing portions of the conductive foil using known photo-imaging techniques to leave remaining an interconnecting conductive circuit projecting in part into the perimeter of a preselected volume of the dielectric substrate material. Then, using photo-imaging techniques, the conductive foil from the bottom side of the laminated dielectric substrate is removed within the perimeter of the preselected volume to expose the dielectric substrate material within the said perimeter. Next, the volume of the dielectric substrate material within said perimeter is removed by laser ablation to create a void in the dielectric substrate material without destroying the part of the interconnecting conductive circuit projecting into the perimeter of the void. Then, an electronic component is inserted into the void, preferably, having a thickness not greater than the preselected thickness of the laminated dielectric substrate and having at least one contact corresponding in position to the part of said interconnecting conductive circuit that projects into the perimeter of the void so that when fully inserted, the contact on the electronic component registers with and contacts said projecting part of the interconnecting conductive circuit. Finally, the contact on the electronic component and the projecting part of the interconnecting conductive circuit are bonded together (preferably by ultrasonic bonding) to hold the electronic component in the void of the dielectric substrate material.

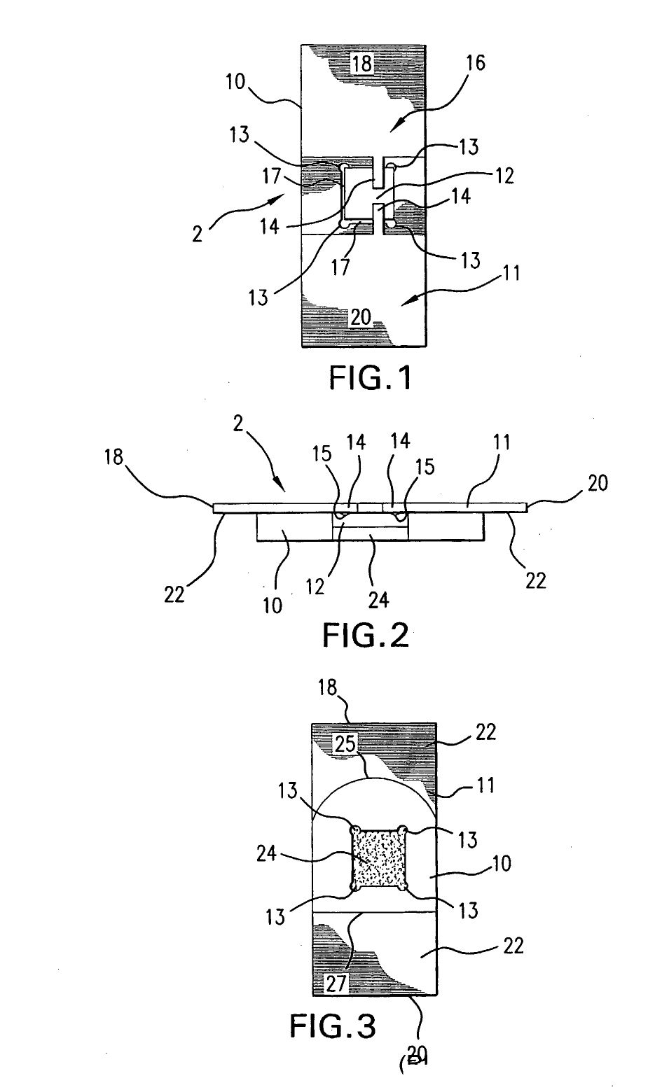

FIGS. 1, 2 and 3 illustrate an interposer 2 manufactured in the above-described manner which results in an electrical connection which is 18 microns in thickness and unobstructed by dielectric material. As shown, a flexible substrate 10 composed of a dielectric material, such as, PET or LCP or other suitable dielectric plastic material, with a copper film 11 laminated on the top side, has embedded therein an electrical device (i.e. semiconductor, resistor, capacitor) or a electro mechanical device ( switch, sensor, connector). As shown, by way of non-limiting example, is an RFID device 12 (e.g. IGN 0205 UCODE) interconnected by tabs 14, ultrasonically or otherwise bonded to the contacts 15 on the RFID device 12. Whereas the cavity created by laser ablation has to be at least the complementary size and shape of the chip 12, it is preferably made slightly larger (see reference numeral 17) than the chip 12 by about 12 microns on two adjacent sides and provided with small relief recesses 13 at the corners. The tabs 14 are part of the interconnect circuit 16 consisting of a first, e.g. power, interconnect 18 and a second, e.g. ground, interconnect 20. The top copper film can be from 12 to 20 microns thick and is shown in the figures as ½ oz copper and is only 18 microns thick. As will be noted in FIGS. 2 and 3, the copper film 11 and interconnects 18 and 20 extends over the dielectric substrate 10 to form flanges 22. Flanges 22 and interconnects 18 and 20 can be bonded (e.g. ultrasonic bonding) or soldered to contacts or connections of an electrical circuit on a PCB or further substrate that the interposer 2 is mounted to. The circuit contacts or connections on the PCB or other substrate are preferably copper. The space behind the chip, RFID device, in the substrate is filled with a conformal coating 24 of an epoxy, e.g. Dymax 9616 made by the Dymax Corporation, Torrington, Conn. 06790. Although the substrate 10 may be symmetrical, it is preferred that substrate 10 has its periphery shaped or profiled so that it can be connected to a PCB or another substrate in only one manner. To this end, by way of example, the substrate 10 is shown in FIG. 3 with an arcuate periphery 25, preferably with a preselected radius, on one side or end, and a straight line 27 on the other side or end. The cavity formed in the PCB or other substrate has a complementary shape, so the interposer 2 only fits in one orientation.

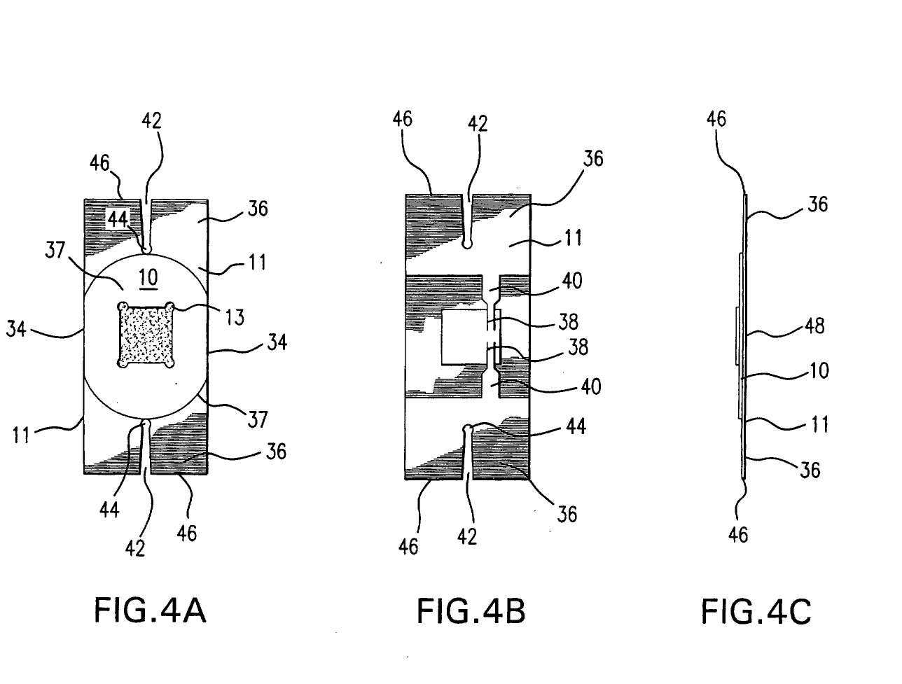

FIGS. 4A, B and C show a preferred version of an interposer 2 containing an RFID chip, such as a IGN 0205 UCODE that is subsequently mounted on a PCB, other substrate or a carton or the like an attached to an antenna, which is preferably printed. The flexible substrate 10 is PET with a thickness of about 0.125 mm and has a copper film 11 about 13 microns in thickness laminated to it. The substrate 10 is circular with opposite chords removed at edges 34. The copper film 11 overhangs the arcuate areas 37 of the substrate 10 to form flanges 36 at either end of the structure. The RFID device is mounted in the substrate in the manner described above and the interconnects 40 extend from the tabs 38 to the flanges 36. Both flanges 36 have a cutout 42 extending in the longitudinal direction of the structure which is elongated. The cutouts or recesses 42 initiate from a well 44 close by the substrate arcuate edge 36 and gradually enlarge toward the edges 46 of the flanges 36 to form a very shallow V configuration, and serve as an ink capillary. As noted the back of the RFID device is filled in with epoxy and a conformal coat 48 is coated on the substrate 10 back and over the RFID device on top. The final thickness at the conformal coats 48 of the structure is about 0.200 mm. Other dimensions of the structure are marked on the drawings of FIGS. 4A, B and C and incorporated herein by reference.

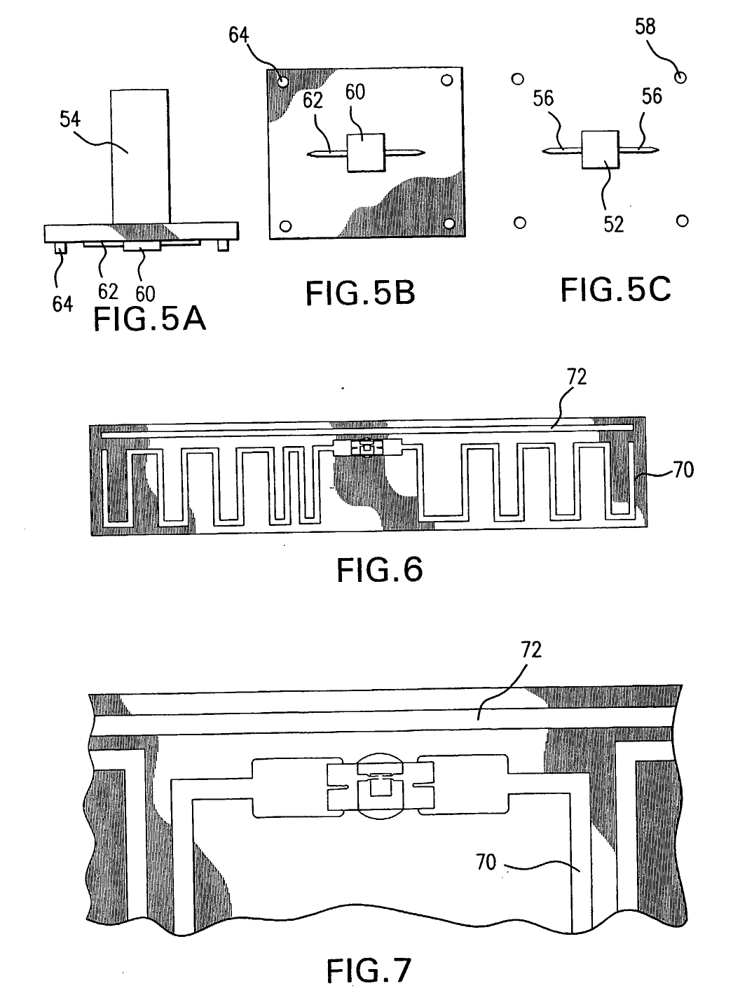

The mounting of the structure of FIGS. 4A, B and C (the interposer) is shown in FIGS. 5A, B and C, 6, 7 and 8. A second PET substrate 50 is used by way of example, but could be a PCB or a carton or the like and contains electrical interconnections or circuitry. The PET material is prepared for the placement of the component by punching a hole 52 through the material which is of the size to facilitate receiving the body of the interposer 2 while allowing the micro flange 36 to rest on the surface of the material. A punch tool 54 with a cavity punch 60, embossing rivulets 62 and registration pins 64 is manufactured in a manner which embosses the PET substrate 50 on the top mounting surface with rivulets 56 while punching the cavity 52. Registration holes 58 are also punched into the PET substrate when the cavity of the interposer is punched. The interposer 2 is placed in the cavity 52 and conductive material 70 is printed on the substrate 50 that overlaps the flanges 36, and runs down the rivulets to the wells, in order to gain an excellent electrical contact with the interposer 2. The printed image on the substrate can be an antenna pattern, as shown, or any other pattern. As shown in FIGS. 6 and 7, a printed strip 72 is also included to act as a sympathetic capacitance for the antenna 70. Alternative to a printed antenna which can be on the front or back of the substrate, a copper film antenna can be made on the PET substrate 50 using photo imaging techniques well known to those skilled in the art, whereupon, the flanges 36 of the interposer 2 are bonded to the connects of the copper film antenna (in the form of antenna 70 and strip 72) when placing the interposer 2 in the PET substrate 50 using Ag ink or SnPb solder and fill with conformal material. For creating a printable format for items such as employee badges, credit cards, RF antennae for tagging items, a PET sheet of predetermined size (i.e. 300 mm×450 mm) will be punched for multiple images. A component interposer 2 will be placed at the designated location for each printable image. Multiple sheets may be prepared in this manner and stacked. The stack of PET sheets is placed in a platen press and heated at 175° C. for 35 minute at 2500 PSI.

When thoroughly processed, the PET material of the substrate will have reached near melting temperature and the bottom surface of the interposer micro flange will have been compressed and fused into the PET substrate material and will have formed a planarized and contiguous surface and structure. As described, the sheet of PET material with embedded micro flange components has been prepared for printing using a conductive material. As an example of such materials, see the products of Parelec, Inc. of Rocky Hill, N.J.

As an alternative method to the foregoing, a micro flange component may be employed in a site specific location by the following method. A PET or similar material substrate is used to manufacture a membrane switch or item which requires several electrical or electro mechanical devices place in discreet locations prior to printing conductive material. A cavity is punched in the desired location along with at least two registration holes. The substrate material is preheated to a low and compliant temperature (about 135° C. for PET ) in an oven or with a hot plate. The component to be attached is placed in the cavity with the micro flange resting on the top surface. A manual heating iron with registration pins is placed over the component and with downward applied pressure the part is embedded into the material.

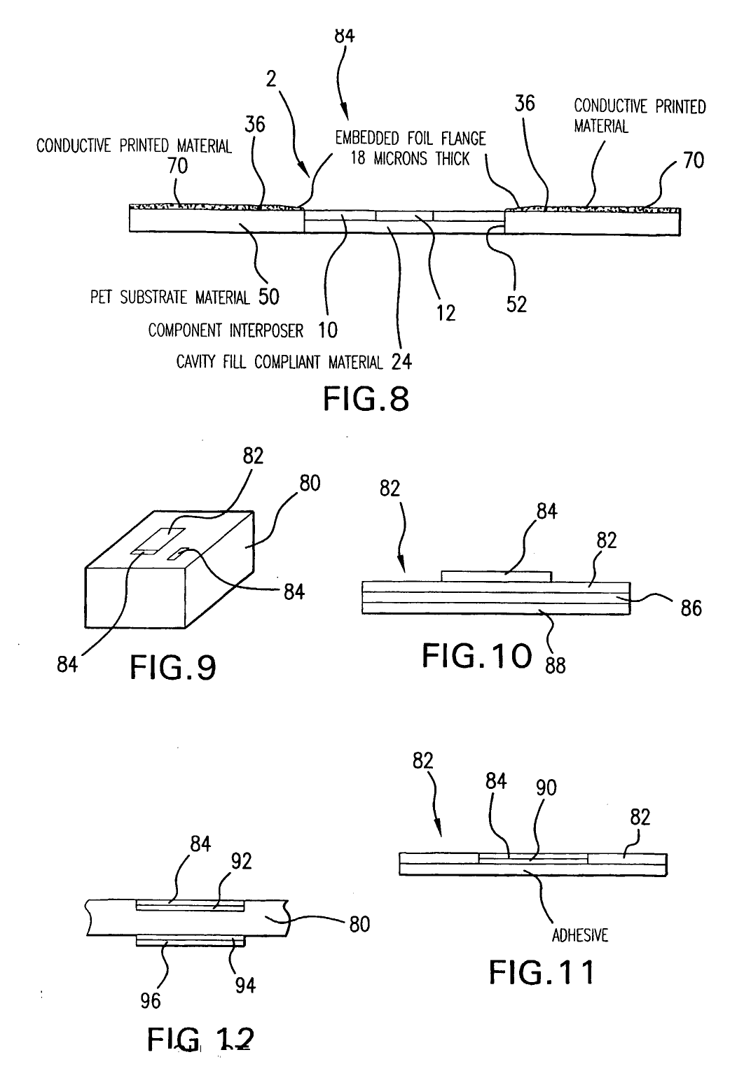

FIG. 9 is an illustration of a carton 80 with a label 82 adhesively secured to the carton 80 which includes the structure 84 of FIG. 8, and alternatively with the structure 84 of FIG. 8 adhesively mounted to the carton 80.

The label is shown in a variety of formats in FIGS. 10-12. In FIG. 10, the structure 84 is adhesively secured to the top of the label, and a conductive film 86 is secured to the back of the label to serve as a sympathetic capacitance for the antenna on structure 84. An adhesive backing 88 is present to secure the label to the carton 80. In FIG. 11, the structure 84 is embedded into the label with a backing of a conductive film 90 and an adhesive coating to attachment to a carton 80. FIG. 12 shows a wall of carton 80 with the structure 84 adhesively held by coating 92 embedded and a conductive film 94 adhesively held by coating 96 to the inside surface of the carton. Alternatively, structure 84 could be embedded in the carton wall and the antenna printed on the carton with conductive ink in the manner described in conjunction with FIGS. 4-8.

Although the invention has been shown and described with respect to specific embodiments, changes and modifications are possible without departing from the inventive concepts as expressed in the claims. Such changes and modifications are deemed to fall within the purview of the invention as claimed.

1. A micropackage comprising: a. a flexible dielectric plastic substrate composed of a dielectric layer with a layer of conductive film on one surface; b. at least two electrical interconnects each including a tab formed in the copper film on said one surface, said interconnects extending out over the edges of the plastic substrate in at least two directions to form at least two flanges; c. a cavity formed in said plastic substrate such that the tabs of the at least two interconnects extend into said cavity; and d. one of an electrical device and an electro mechanical device having contacts received in the cavity of the plastic substrate with its contacts engaged with and bonded to the tabs of the interconnects.

2. A micropackage according to claim 1 wherein the substrate is profiled to provide orientation when mounting.

3. A micropackage according to claim 1 wherein the conductive film is copper.

4. A micropackage according to claim 1 wherein the flanges have a shallow V-shaped recess in their free edges to act as an ink capillary.

5. A micropackage according to claim 1 wherein a slight space exists adjacent the device received in the cavity.

6. A micropackage according to claim 1 wherein at least one corner of the cavity has a relief recess.

7. A micropackage according to claim 1 wherein a conformal coating covers the device.

8. A method of making a micropackage comprising the steps of: a. providing a flexible dielectric plastic substrate composed of a dielectric layer with a layer of conductive film on one surface; b. forming at least two electrical interconnects each including a tab in the copper film on said one surface, with said interconnects extending out over the edges of the plastic substrate in at least two directions to form at least two flanges; c. forming a cavity in said plastic substrate such that the tabs of the at least two interconnects extend into said cavity; d. positioning one of an electrical device and an electro mechanical device having contacts in the cavity of the plastic substrate with its contacts engaged with the tabs of the interconnects; and e. bonding the contacts to the tabs.

9. A method of making a micropackage according to claim 8 including the further step of profiling the substrate to provide orientation when mounting.

10. A method of making a micropackage according to claim 8 wherein the conductive film is copper.

11. A method of making a micropackage according to claim 8 including the further step of forming the flanges with a shallow V-shaped recess in their free edges to act as an ink capillary.

12. A method of making a micropackage according to claim 8 including the further step of providing relief for the device received in the cavity.

13. A method of making a micropackage according to claim 8 including the further step of coating the device with a conformal coating.

14. A micropackage comprising: a. the micropackage of claim 1, as an interposer, mounted in a cavity in a second substrate or PCB having electrical connections; and b. the flanges of the interposer being fixed to the electrical connections.

15. A micropackage according to claim 14 further including an antenna on the second substrate coupled to the electrical connections.

16. A micropackage according to claim 15 wherein the antenna is a conductive ink.

17. A method of making a micropackage comprising: a. using the micropackage of claim 1 , as an interposer; b. mount the interposer in a cavity in a second substrate or PCB having electrical connections; and c. fixing the flanges of the interposer to the electrical connections.

18. A method of making a micropackage according to claim 17 including the further step of forming an antenna on the second substrate coupled to the electrical connections.

19. A method of making a micropackage according to claim 17 including the further step of forming the antenna on the second substrate using conductive ink.
